(19) United States
(12) Patent Application Publication
(10) Pub. No.: US 2012/0307439 A1
(43) Pub. Date: Dec. 6, 2012

(54) EXTENSION HOLDER APPLIED IN TABLET PC

(75) Inventors: Mao-Huai WENG, New Taipei City (TW); Wen-Chu CHUANG, New Taipei City (TW); Feng-Kao HSIAO, New Taipei City (TW); Jiun-Yi YEH, New Taipei City (TW)

(73) Assignee: ACARD Technology Corp., New Taipei City (TW)

(21) Appl. No.: 13/211,460

(22) Filed: Aug. 17, 2011

(30) Foreign Application Priority Data
May 30, 2011 (TW) 100209751

(51) Int. Cl. H05K 5/00

(52) U.S. Cl. 361/679.4

(57) ABSTRACT

An extension holder applied in tablet PC primarily includes a tablet PC and an extension holder, wherein the tablet PC is secure inserted into the holding space onboard the said extension holder which is further configured with at least a peripheral extension port, enriches the function and convenience of the tablet PC, and provides the holding safety of tablet PC against any damage resulted from slipping or dropping to the ground.

### BACKGROUND OF THE INVENTION

1. Field of the Invention

The present invention is related to an extension holder applied in tablet PC and more particularly to an assembly of a tablet PC and the extension holder, which enhances more application and ability of the tablet PC through the connection from each other to offer easy and user-friendly operations, provides better and secure holding safety free from any damage due to the slippery and insufficient holding area, and is suitably applied in a variety of tablet PCs and those similar electronic devices.

2. Description of Related Art

Due to the speedy progress of technology, tablet PCs had been a very popular and advanced electronic communication device recently. And, what's more, they might lead and take the place of laptop (notebook) PCs in the near future if the market follows this technology-oriented, tiny and slim tablet trend.

As the tablet PCs had become accepted by more and more worldwide users, under such a circumstance, the tablet PCs' manufactures had been trying to reduce or simplify those existed function and/or hardware used to be configured inside those prior laptop or desktop PCs to provide a better weight scale and basic function which we had been used to operate and know very before.

The drawbacks we user face immediately is we users' convenience and the safety of tablet PC itself. Owing to the tiny, slim design and manufacturing, the tablet PC usually is lack of a holding device and that endangers the damage resulted from slippery and dropping to the ground. Even there are some covers which could be purchased to have a protection, tablet PCs is still assume the risk to damage, but also configured with simplified hardware structure and function. There might be not enough extension port or less connection ability by the trade-off of light, tiny and slim trend.

Thus, in view of the above-mentioned problems, the present invention aims to provide an extension holder applied in tablet PC which offers an to extension holder to enable more secure safety and to increase more communication and operational function of the tablet PCs.

### SUMMARY OF THE INVENTION

The primary objective of the present invention is to provide an extension holder applied in tablet PC, which the extension holder is configured with a holding space to be inserted and fit by the tablet PC via the connection of the adapting port and extension port respectively from each other, and at least a peripheral extension port which comprises but is not limited to a net work socket, a USB socket and a card reader. Through assembly of the extension holder and the tablet PC, the present invention provides a secure holding position and is capable to link and expand with more peripheral devices at the same time.

An another objective of the present invention is to provide an extension holder applied in tablet PC, which the extension holder is configured with a plural of striped grooves at the back side to offer an easier holding toward such a hardware combination of the extension holder and the tablet, and thus the tablet PC has a more safety protection. Besides, plural operational buttons are configured at those plural striped grooves to enable a clear and convenient operation or control.

A further objective of the present invention is to provide an extension holder applied in tablet PC, which a processor is configured within the extension holder and links to the extension port of a tablet PC via an adapting port installed within the holding space, to the described peripheral extension port, to the touch pad or the keypad, and to some other devices, for example, the Input/Output connectors, GPS, RFID system, camera to and/or wireless devices, etc. The extension holder is also configured with a battery to have a power supply itself or performs as a power back-up via a power control unit links to the tablet PC.

Advantageously, the present invention relates to an extension holder applied in tablet PC and more particularly to an assembly of a tablet PC and the extension holder, which provides a secure holding safety for the tablet PC and expands the convenience and function connects to a variety of external devices as mentioned above.

To enable a further understanding of the said objectives and the structural configuration of the present invention, the brief description of the drawings below is followed by the detailed description of the preferred embodiments.

### BRIEF DESCRIPTION OF THE DRAWINGS

FIG. 1 is a schematic diagram of an embodiment according to the present invention;

FIG. 2 is a decomposition diagram of the present invention,

FIG. 3 is a schematic diagram of the extension holder,

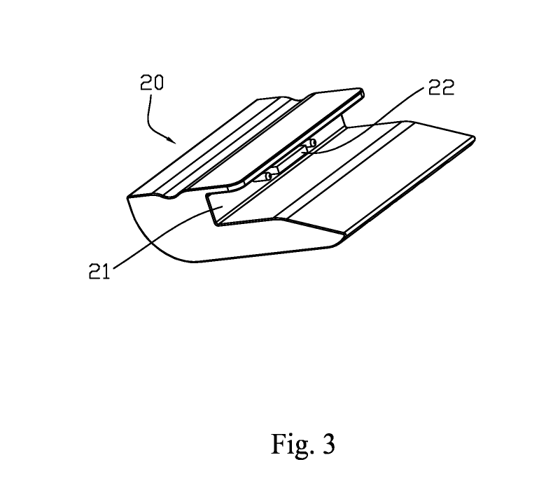

FIG. 4 is a schematic side view of the present invention,

FIG. 5 is a schematic back view of the present invention, and

FIG. 6 is a structural block diagram of the present invention.

| | | | |
|---|---|---|---|
| 10 | tablet PC | 11 | extension port |
| 20 | extension holder | 201 | GPS |
| 202 | RFID system | 203 | camera |
| 204 | key pad | 205 | touch pad |
| 206 | wireless device | 207 | Input/Output connector |
| 21 | holding space | 22 | adapting port |
| 23 | peripheral extension port | 231 | USB socket |
| 232 | network socket | 233 | card reader |
| 24 | striped groove | 241 | button |
| 25 | battery | 251 | power control unit |
| 26 | processor | | |

### DETAILED DESCRIPTION OF THE PREFERRED EMBODIMENTS

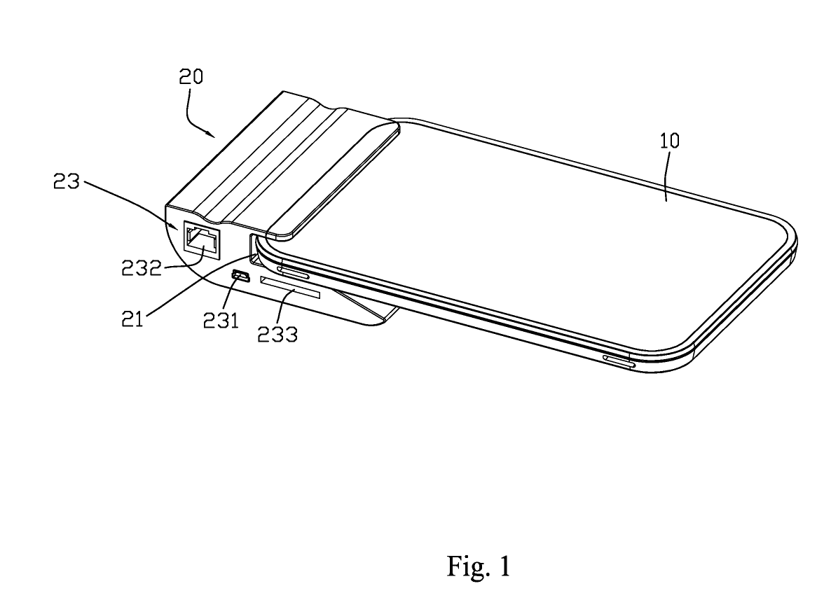

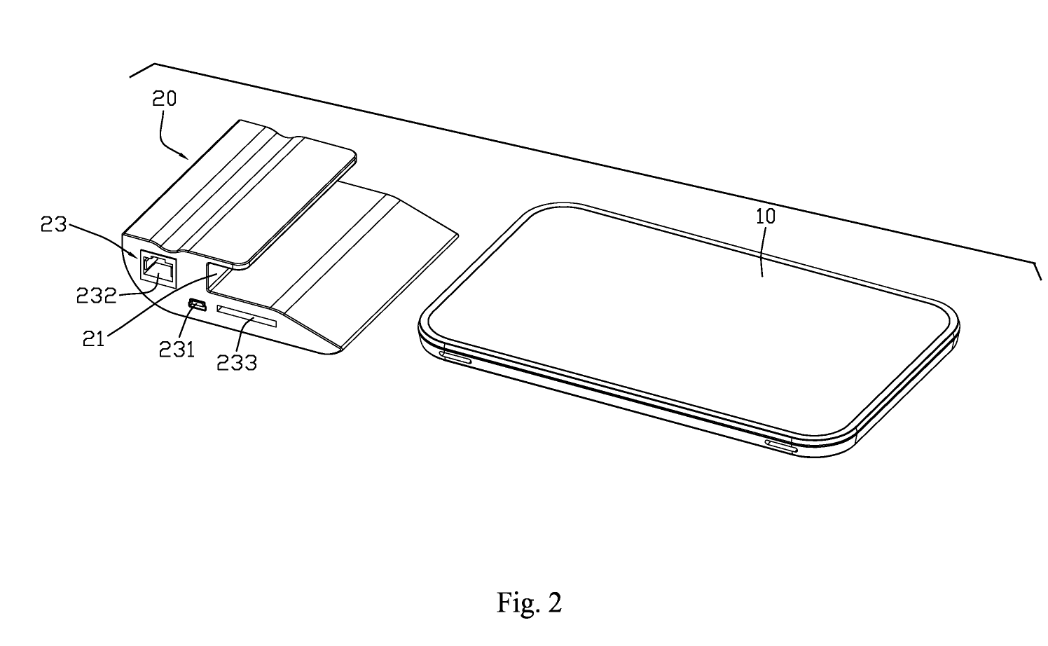

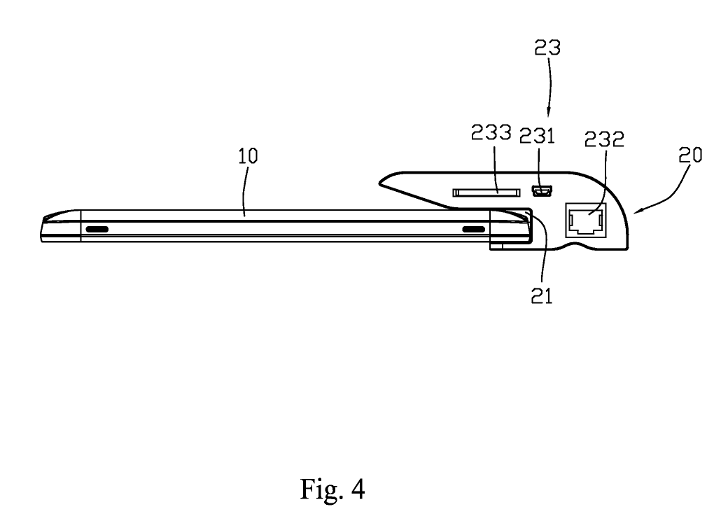

Please refer to Figures from 1 to 6, which respectively show some schematic views and explanation related to the present invention. The present invention is related to an extension holder applied in tablet PC and more particularly to an assembly of a tablet PC 10 and the extension holder 20 (shown in FIG. 1). The said extension holder 20 is configured with a holding space 21 to be inserted and fit by the tablet PC 10 via the electrical connection of the adapting port 22 (shown in FIG. 2) and extension port 11 respectively from each other for control and data communication, and at to least a peripheral extension port 23 (shown in FIG. 4), located at one side of the extension holder 20, which comprises but is not limited to a net work socket 232, a USB socket 231 and a card reader 233 to extend multi function and access to the external. As not shown in the figures, the peripheral extension port 23 could be a further alternative composition with a printer port, D-sub display connector and/or other digital interface, etc. The present invention needs to be specified is that the adapting port 22, for instance, an USB interface or a 30-pin docking port supports function of Plug- and Play and hot attach & detach. The said extension holder 20 is also configured with a battery 25 to have a power supply itself or performs as a power back-up via a power control unit 251 links to the tablet PC 10.

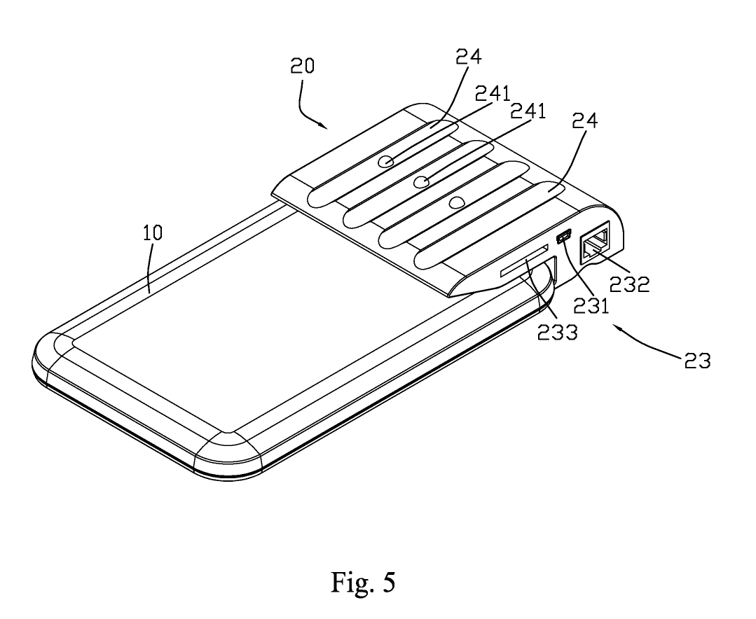

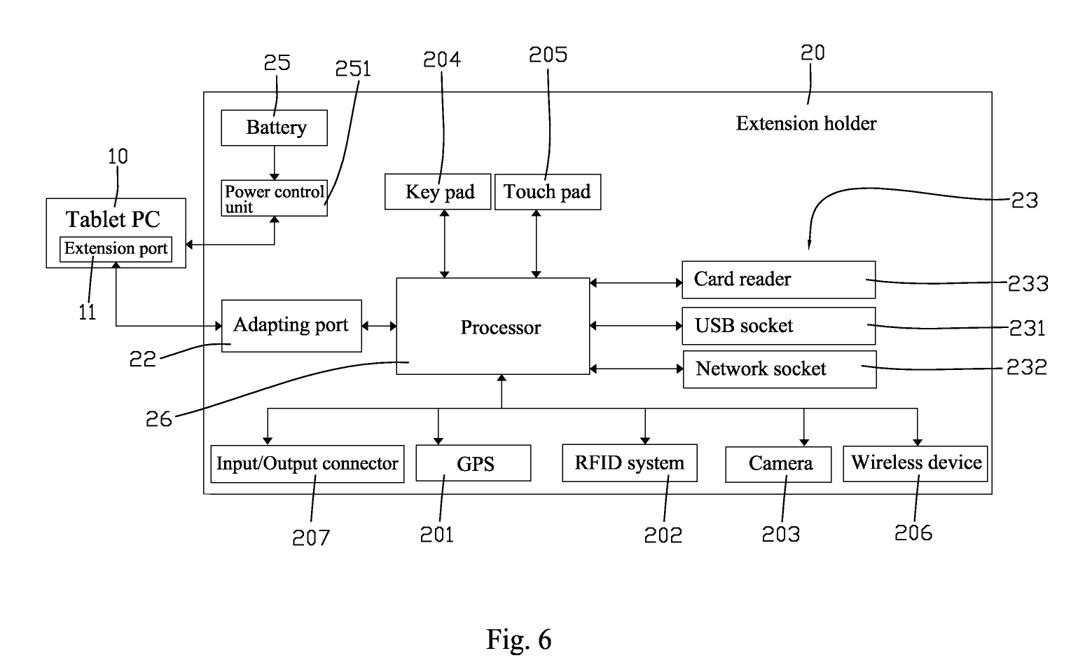

And, the back side of the extension holder 20 is configured with a plural of striped grooves 24 (shown in FIG. 5) for a more secure holding toward the hardware combination of the extension holder 20 and the tablet 10, and some operational buttons 241 are configured at those plural striped grooves to enable a clear and convenient operation or control. Besides, a processor 26 (shown in FIG. 6) is configured within the extension holder 20 and links to the extension port 11 of a tablet PC 10 to control the entire operation via an adapting port 22 installed within the holding space 21, to the above-mentioned peripheral extension port 23, to the touch pad 205 or the keypad 204, and to some other devices by cable or wireless mode, for example, the Input/Output connectors 207, GPS 201, RFID system 202, camera 203 and/or wireless devices 206 such as Bluetooth, GSM, GPRS or Wi-Fi. Alternatively, the extension holder can be equipped with a strap (not shown in figures) for the user to hold by hand or body, and a fixing structure (not shown in figures) might be applied for the hardware assembly to of a tablet PC 10 and the extension holder 20.

The above-mentioned description of the present invention has been presented for purpose of illustration and is not intended to be exhaustive or to limit the invention.

It is of course to be understood that the embodiments described herein is merely an illustration related to the principles of the invention and that a wide variety of modifications thereto may be accomplished by persons skilled in the art without departing from the scope of the invention as set forth in the following claims.

What is claimed is:

1. An extension holder applied in tablet PC, comprising:
a tablet PC, which is configured with an extension port; and
an extension holder, which is configured with a holding space to be inserted and fit by the tablet PC via the connection of the extension port of the tablet PC and the adapting port configured in the holding space, and at least a peripheral extension port.

2. An extension holder applied in tablet PC according to claim 1, wherein the extension holder is configured with a plural of striped grooves at the back side and plural operational buttons are configured at those plural striped grooves.

3. An extension holder applied in tablet PC according to claim 1, wherein the extension holder is configured with a battery and links to the tablet PC via a power control unit.

4. An extension holder applied in tablet PC according to claim 1, wherein the extension holder is configured with a touch pad or a keypad.

5. An extension holder applied in tablet PC according to claim 1, wherein the extension holder is configured with a processor which links to the adapting port, the peripheral extension port, the touch pad or the keypad

6. An extension holder applied in tablet PC according to claim 5, wherein the processor also links to the Input/Output connectors, GPS, RFID system, camera and/or wireless devices.

7. An extension holder applied in tablet PC according to claim 1, wherein the peripheral extension port comprises any composition of a net work socket, a USB socket, a card reader, a printer port, a D-sub display connector and/or digital display interface.

8. An extension holder applied in tablet PC according to claim 1, wherein the adapting port of the extension holder is an USB interface or a 30-pin docking port.

9. An extension holder applied in tablet PC according to claim 1, wherein the extension holder is equipped with a strap and a fixing structure is applied in the tablet PC.
